(19) United States
(12) Patent Application Publication
(10) Pub. No.: US 2005/0186798 A1
(43) Pub. Date: Aug. 25, 2005

(54) Process for manufacturing semiconductor devices and related semiconductor device

(75) Inventors: Daniele Bertone, Torino (IT); Simone Codato, Torino (IT); Roberta Campi, Torino (IT)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: AgilentTechnologies, Inc.

(21) Appl. No.: 11/040,540

(22) Filed: Jan. 21, 2005

(30) Foreign Application Priority Data
Feb. 25, 2004 (GB) 0404157.0

(51) Int. Cl. H01L 21/461

(52) U.S. Cl. 438/689

(57) ABSTRACT

A process for manufacturing semiconductor devices including a plurality of semiconductor layers arranged over a substrate, the semiconductor layers including at least one active layer. The process comprises the steps of vertically etching the plurality of semiconductor layers, the vertical etching including reactive ion etching of the semiconductor layers, and a subsequent regrowth of the laser structure in a regrowth reactor. The process includes the step of in-situ etching the laser structure in the regrowth reactor after the reactive ion-etching step. The process is effective in obtaining smooth planar and lateral surfaces for the regrowth step.

The present invention relates to techniques for manufacturing semiconductor devices and was developed by paying specific attention to the possible application to Multi Quantum Well (MQW) lasers.

Reference to this preferred field of application is not however to be construed in a limiting sense of the object and scope of the invention.

Manufacturing of semiconductor devices frequently requires vertical etching steps to produce structures extending across the different semiconductor layers.

In Situ Etching (ISE) of layered structures is technologically advantageous for the fabrication of optoelectronic devices, in particular laser devices.

Specifically, ISE is a technique that enables the etching of III-V semiconductor materials in any epitaxial reactor working both at atmospheric and at low pressure.

In Situ Etching may be applied to any epitaxial technique working far from the thermodynamic equilibrium such as MOVPE (Metal Organic Vapour Phase Epitaxy), CBE (Chemical Beam Epitaxy), HVPE (Hydride Vapour Phase Epitaxy) and MOMBE (Metal Organic Molecular Beam Epitaxy). This usually occurs just before re-growth, using halogen-based compounds as the etchant precursors. While adapted for several purposes, ISE finds its principal application in the etch/regrowth of high performance buried structures required for advanced devices.

Reactive Ion Etching (RIE) is a standard technique resorted to producing mesa structures for etching the III-V semiconductor material, followed by an etching step performed with different aqueous acid solutions. Then the sample is loaded into the reactor and the regrowth step is performed.

Conversely, the ISE process is performed in the reactor and does not involve the use of aqueous solutions. The ISE process and the regrowth steps are performed in a controlled reactor environment, with no exposure to external contaminants, and this is greatly advantageous in terms of reproducibility and control of the whole process.

The ISE technique thus seems to be the most promising technique for dispensing with the difficulties encountered in the manufacture of buried structure devices that contain aluminium in the active region: this group III material is in fact particularly sensitive to oxidation and contamination, which may lead to serious problems in terms of device reliability and performance.

The solution currently adopted is performing an ISE process on a substrate patterned with dielectric mask material e.g. silicon dioxide (SiO₂) masks. Many halogen compounds, in particular chlorinated compounds, are adopted in the ISE process as function of the reactor used. In a MOVPE reactor mainly tertiary-butyl-chloride (TBCl) is used. Such an approach leads to smooth planar and lateral surfaces if the etched material is indium phosphide (InP).

Similar processes applied to standard InGaAsP and AlGaInAs heterostructures are known, for instance, from R. Gessner et al. “Fabrication of AlGaInAs and GaInAsP buried heterostructure lasers by in-situ etching”; Journal of Crystal Growth, 248, (2003), 426-430.

However, this approach usually determines the absence of or a very small undercut in the etched structure and leads to strong difficulties in etching aluminium alloys.

To overcome this problems a new approach, that is a combination of a Reactive Ion Etching and an In Situ Etching, has been developed.

The article by P. Wolfram et al. “MOVPE-based in situ etching of In(GaAs)P/InP using tertiarybutylchloride”; Journal of Crystal Growth, 221, (2000), 177-182, discloses an ISE process using tertiary-butyl-chloride on a InP substrate, where a RIE process is preliminarily applied to the material. Such a document however does not refer to applying the process to standard InGaAsP active structures or to aluminium-containing active structures.

The object of the present invention is to provide an improved manufacturing process of semiconductor devices comprising an etching process.

Specifically, the object of the present invention is an improved manufacturing process that facilitates the etching of standard InGaAsP and aluminium-containing structures and ensures the presence of an undercut in the etched structure. It also helps in avoiding formation of surface defects and deep trenches if any group III precursor is added during the process.

According to the present invention, that object is achieved by means of a process having the features set forth in the claims that follow. The invention also relates to a corresponding semiconductor device.

A preferred embodiment of the invention is applied to manufacturing a laser device comprising a Multi Quantum Well (MQW) structure: in a first step the structure is etched by means of a reactive ion etching process down through the active material to the InP buffer layer and then an in-situ etching process is performed on the obtained structure. Such an approach avoids defects on the surface, while defining a mesa with an appreciable undercut and overcoming the problem of etching aluminium-containing materials.

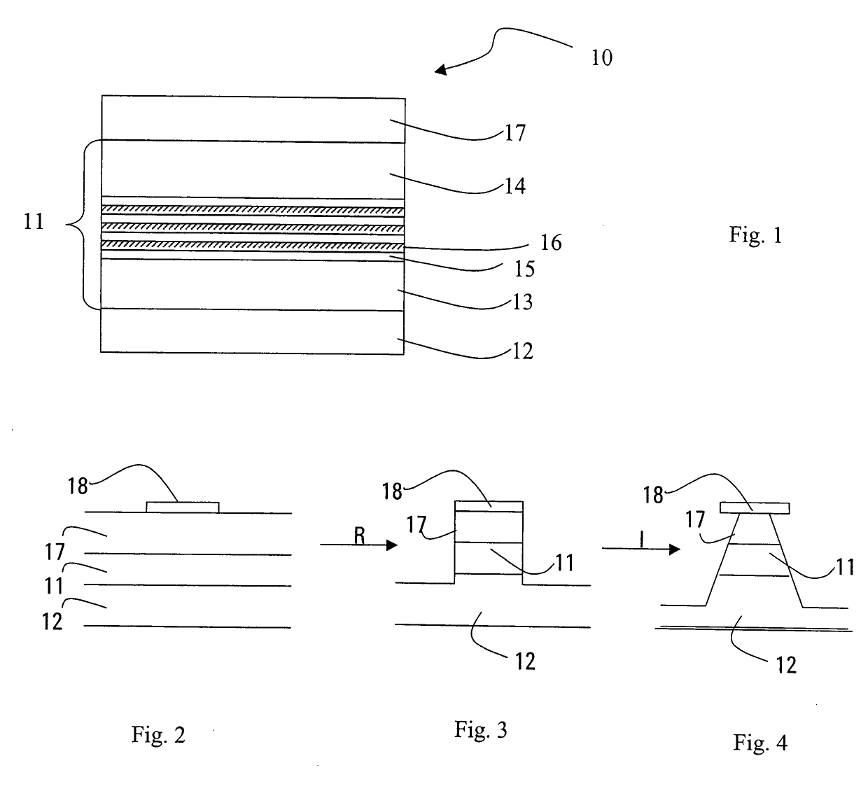

The invention will now be described, by way of example only, with reference to the annexed figures of drawing, wherein:
FIG. 1 is a cross-sectional side view of a semiconductor laser structure in a first step of the etching process described herein; and
FIGS. 2 to 4 are schematic views exemplary of further steps in the etching process described herein.

FIG. 1 is a schematic cross sectional side view of the basic planar structure 10 of a semiconductor laser.

Such a laser structure 10 comprises a Multi Quantum Well (MQW) structure 11, including a sequence of AlGaInAs/AlGaInAs layers.

Such a laser structure 10 is manufactured using an in-situ etching process that provides for combining RIE and ISE techniques for the definition of the mesa, using TBCl as etchant precursor, as will be better detailed with reference to FIGS. 2, 3 and 4.

More in detail, the exemplary laser structure 10 considered herein comprises a first buffer layer 12 of epitaxial indium phosphide, InP, having a photoluminescence peak at a wavelength of 0.918 micrometer and n-doped with e.g. 2*10¹⁸ at/cm³.

For the purposes of this description, the first buffer layer 12 can be regarded as a substrate onto which a first separate confinement heterostructure (SCH) layer 13, belonging to the MQW structure 11, is arranged. Such a first SCH layer 13, operating as a confinement layer, has a photoluminescence peak at a wavelength of e.g. 1011 nanometers, a thickness of e.g. 65 nanometers and is undoped.

The lattice mismatch of the first SCH layer 13 is nearly zero.

The MQW structure 11 further comprises a sequence of barrier layers 15, peaked at a wavelength of e.g. 1011 nanometers, and well layers 16, peaked at a wavelength of e.g. 1400 nanometers.

The barrier layers 15 have a lattice mismatch of e.g. −0.5% and a thickness of e.g. 7.5 nanometers, while the well layers 16 have a lattice mismatch of e.g. +0.72% and a thickness of e.g. 5.7 nanometers.

To complete the confinement structure, a second SCH layer 14, analogous to the first SCH layer 13, is arranged over the stack made of barrier layers 15 and well layers 16. Finally, a second cap layer 17 of Zn doped indium phosphide, having a thickness of e.g. 300 nanometers, is placed over the MQW structure 11. The doping level is e.g. 5*10¹⁷.

As shown in FIG. 2, the laser structure 10 is further patterned with SiO₂ stripes 18, e.g. 3 micrometers wide, intended to act as the masks for the subsequent mesa definition step.

After deposition of stripes 18, a reactive ion etching process, indicated by the reference R, is performed on the laser structure 10. Such a reactive ion etching process R fully removes the unmasked material, i.e. the indium phosphide cap layer 17, the MQW structure 11, reaching the first buffer layer 12. The resulting structure after such reactive ion etching process R can be observed in FIG. 3.

Subsequently, the laser structure 10 is cleaned e.g. in an aqueous solution of KOH for one minute and then in e.g. H₂SO₄ for three minutes.

Then the laser structure 10 is loaded into a regrowth reactor such as an epitaxial reactor as used for the MOVPE process, where an ISE process, indicated with the reference I, is performed, using TBCl in a mesa-type etch. Other types of regrowth reactors can be used within the framework of the arrangement described herein such as a Molecular Beam Epitaxy reactor, a Chemical Beam Epitaxy reactor and an Hydride Vapour Phase Epitaxy reactor as used for the MOMBE, CBE and HVPE process respectively.

The mesa structure of the resulting laser structure 10 is shown in FIG. 4.

In order to complete the laser structure 10, the proposed manufacturing process comprises further steps: these process steps are well known to those of skill in the art, and are not shown in the figures.

First, a regrowth step of a lateral current blocking structure (e.g. InP:Fe—In:P:Sn) is performed.

Then a removal step of the SiO₂ stripe 18 operating as a mask is carried out with HF aqueous solution. Finally cladding (e.g. InP:Zn) and contact (e.g. InGaAs:Zn) layers are grown.

The subsequent technological steps are those currently adopted in a standard procedure for manufacturing of Fabry Perot lasers.

The technique described in the foregoing can be applied in a thoroughly reliable manner to the manufacture of devices based on III-V semiconductor materials, by producing structures having a smooth surface as well as a well defined undercut, while avoiding the formation of deep trenches. Additionally, the vertical shape initially bestowed on the reactive ion etching process can be preserved.

The technique described in the foregoing also allows etching of aluminium containing materials, leading to devices with improved performances.

The advantages inherent in the technique described in the foregoing facilitate the mesa definition in particular with aluminium-containing structures and the following regrowth of blocking layers in buried heterostructures.

Strong etching conditions are required in order to laterally etch the active material containing aluminium. This could lead to roughness and defects on the etched surface. The addition of TMGa (trimethyl gallium) during the etching is helpful in solving this issue, as this enhances the lateral etching rate of the aluminum-containing structure. It also reduces the etching rate on the surface.

This leads to a better control of the etching process and, at the same time, allows etching of active materials containing aluminium under mild conditions, which in turn leads to better morphologies of the etched surface.

The scope of the invention thus encompasses alternative techniques combining a reactive ion etching process and ISE process assisted by TMGa. The use of other species, like In, Al, Fe, Sn, Si, S and Zn precursors, TertiaryButyl Arsine (TBAs), TertiaryButyl Phosphine (TBP), Phosphine (PH₃) and Arsine (AsH₃), during the etching is also possible.

The chlorinated compound used as an etchant in association with the proposed process is preferably TBCl; CH₂Cl₂ represents a possible alternative, although such a compound is not adopted in literature as an etchant.

The proposed manufacturing process also applies to devices such as e.g. Distributed Feedback Lasers (DFB) and Electro Absorption Modulators (EAM), Semiconductor Optical Amplifiers (SOA), Distributed Bragg Reflectors (DBR) and can be extended also to standard InGaAsP materials. The proposed process can also be extended just to obtaining trenches or ridges or for other type of regrowth processes. A possible application is in the production of integrated devices with e.g. Selective Area Growth (SAG) or e.g. Butt Joint (BJ) technique.

The proposed manufacturing process applies not only to devices having Multi Quantum Well (MQW) structures as active layer but also bulk (mono layer) materials or a combination of bulk and MQW structures, like e.g. waveguides.

Consequently, without prejudice to the underlying principle of the invention, the details and embodiments may vary, also significantly, with respect to what has been described in the foregoing, by way of example only, without departing from the scope of the invention as defined by the claims that follow.

1. A process for manufacturing semiconductor devices including a plurality of semiconductor layers arranged over a substrate, said plurality of semiconductor layers including at least one active layer, said active layer comprising aluminium, the process comprising the steps of:
vertically etching said plurality of semiconductor layers, said vertical etching including reactive ion etching of said semiconductor layers, and
subsequent regrowth of said substrate in a regrowth reactor,
wherein the process includes the step of in-situ etching said substrate using at least one halogen-based compound in said regrowth reactor after said reactive ion etching step.

2. The process of claim 1, wherein said at least one halogen-based compound includes TBCl.

3. The process of claim 1, wherein said at least one halogen-based compound includes CH₂Cl₂.

4. The process of claim 1, wherein the process further comprises the step of adding TMGa during said in situ etching step.

5. The process of claim 1, wherein the process further comprises the step of adding a species or a combination of species selected among In, Ga, Al, Fe, Sn, Si, S, Zn, N, P and As precursors during said in situ etching step.

6. The process of claim 1, further including a cleaning step prior to said in-situ etching step.

7. The process of claim 1, wherein said reactive ion etching step of said semiconductor layers reaches said substrate layer.

8. The process of claim 1, wherein said regrowth reactor is an epitaxy reactor.

9. The process of claim 8, wherein said epitaxy reactor is selected from a Metal Organic Vapour Phase Epitaxy (MOVPE) reactor, a Chemical Beam Epitaxy (CBE) reactor, an Hydride Vapour Phase Epitaxy (HVPE) reactor and a Metal Organic Molecular Beam Epitaxy (MOMBE) reactor.

10. The process of claim 1, wherein said plurality of semiconductor layers includes III-V group semiconductor layers.

11. The process of claim 1, wherein said substrate layer is at least in part an indium phosphide layer or a gallium arsenide layer.

12. The process of claim 1, wherein said active layer comprises InGaAsP.

13. The process of claim 1, wherein said active layer comprises a combination of elements selected in group III elements and elements selected in group V elements.

14. A semiconductor device manufactured with the process of claim 1.

15. The device of claim 14, wherein said device is a laser structure and said active layer is a Multi Quantum Well (MQW) structure.

16. The device of claim 14, wherein said active layer comprises a bulk (mono layer) and/or any combination of bulk materials and/or any combination of bulk and MQW structures.

17. The device of claim 14, wherein said device is a Distributed Feedback Laser (DFB).

18. The device of claim 14, wherein said device is an Electro Absorption Modulator (EAM).

19. The device of claim 14, wherein said device is a Semiconductor Optical Amplifier (SOA).

20. The device of claim 14, wherein said device is a Distributed Bragg Reflector (DBR).
